(19) United States
(12) Patent Application Publication
(10) Pub. No.: US 2025/0231476 A1
(43) Pub. Date: Jul. 17, 2025

(54) FRAME ASSEMBLY USED FOR MOUNTING PELLICLE ON PHOTOMASK

(71) Applicant: S&S TECH Co., Ltd., Daegu (KR)

(72) Inventor: Sang-Min JEONG, Daegu (KR)

(73) Assignee: S&S TECH Co., Ltd., Daegu (KR)

(21) Appl. No.: 18/676,670

(22) Filed: May 29, 2024

(30) Foreign Application Priority Data
Jan. 17, 2024 (KR) 10-2024-0007699
Mar. 4, 2024 (KR) 10-2024-0030406

(51) Int. Cl. G03F 1/64

(52) U.S. Cl. CPC G03F 1/64

(57) ABSTRACT

A frame assembly for mounting a pellicle on a photomask is disclosed. The frame assembly includes a frame to which the pellicle is attached, a stud attached to the photomask, and a fixture that is inserted into the lower side of the frame. The stud and the fixture are magnetically bonded to each other, and a gap of a certain height is created between the photomask and the frame by the stud under the fixture. This eliminates the need for precise alignment of the frame during the mounting process on the photomask, and facilitates the separation of the frame from the photomask for reuse. The formation of the gap eliminates the need for a separate process to create vent holes in the frame.

### CROSS-REFERENCE TO RELATED THE APPLICATION

The present application claims priority under 35 U.S.C. § 119 (a) to Korean Patent Application No. 10-2024-0007699 filed on Jan. 17, 2024 and Korean Patent Application No. 10-2024-0030406 filed on Mar. 4, 2024, in the Korean Intellectual Property Office, the entire contents of which application is incorporated by reference herein in its entirety.

### BACKGROUND

### Field

The presently claimed invention relates to a frame assembly, and more particularly, to a frame assembly for mounting a pellicle on a photomask used in photolithography processes.

### Description of the Related Art

Developments in EUV (Extreme Ultra-Violet) lithography technology, which utilizes EUV exposure light with a wavelength of 13.5 nm to realize micro-patterns, are underway. In lithography processes, photomasks are used as templates for patterning. However, impurities such as particles or foreign materials attached to the photomask can absorb or reflect the exposure light, damaging the transferred pattern. Therefore, to prevent impurities from attaching to the surface of the photomask, a method of mounting a pellicle on the surface of the photomask is employed. With the miniaturization of circuit linewidths, the role of the pellicle in protecting the photomask has become increasingly important due to the reduced size of impurities that can affect pattern damage.

FIG. 1 shows the conventional structure with a mounted pellicle. The pellicle 30 includes a square membrane 20 that transmits exposure light and a border 50 supporting the membrane 20 in its outer region. Typically, the pellicle 30 with such structure is manufactured by forming the membrane 20 on a silicon substrate and then etching the substrate's bottom to form the border 10.

To mount the pellicle 30 on the photomask 60, a frame 50 is installed on top of the photomask 60. The structure with the pellicle 30 mounted on the frame 50 is then mounted on the photomask 60, installing the pellicle 30 atop the photomask 60. Adhesive is applied to the bottom of the frame 50 for bonding between the frame 50 and the photomask 60.

As the exposure process using the photomask 60 is repeated, the pellicle 30 needs to be replaced after reaching the end of its lifespan. Since the frame 50, which is more durable and can be reused, Is uneconomical to replace along with the pellicle 30, a method of replacing only the pellicle 30 and reusing the frame 50 is pursued. To replace the pellicle 30, the frame 50 must first be detached from the photomask 60. This requires separating the frame 30 from the photomask 60 at the adhesive interface between the bottom of the frame 30 and the top surface of the photomask 60, using a separate tool or manually. Therefore, the process for separation is complicated, and there's a risk of damaging the photomask 60 or the frame 50 during the separation operation.

Additionally, in the conventional configuration, very precise positioning alignment is required to mount the frame 50 at the exact location on the photomask 60 during the coupling process.

Furthermore, considering that the EUV exposure process is carried out in a high vacuum and high reciprocating force environment, the membrane 20 should not be damaged by the pressure changes from atmospheric pressure to vacuum. To accommodate these pressure changes, the frame 50 typically has several ventilation holes (not shown) that penetrate laterally. These ventilation holes function to buffer pressure changes by connecting the internal space(S) formed between the membrane 20 and the photomask 60 inside the frame 50 with the external space. Therefore, the formation of ventilation holes in the frame 50 is essential, leading to increased frame manufacturing costs due to the high-precision ventilation hole machining process.

Moreover, in such a conventional configuration, there's a concern that the adhesive applied between the frame 50 and the photomask 60 may act as particles during the EUV exposure process, leading to decreased exposure accuracy.

### SUMMARY

The present disclosure provides a frame assembly for mounting a pellicle on a photomask used in a photolithography process. The frame assembly of the presently claimed invention comprises: a frame mounted on the photomask, the frame on which the pellicle is attached; a stud attached to an upper side of the photomask, the stud being disposed between the photomask and the frame; and a fixture installed by being inserted into a lower side of the frame at a position corresponding to the stud between the photomask and the frame. The stud and the fixture are magnetically bonded to each other, and when bonded, the stud positioned beneath the fixture creates a gap of a certain height between the photomask and the frame.

### BRIEF DESCRIPTION OF THE DRAWINGS

FIG. 1 is a drawing showing the conventional structure with a pellicle mounted.

FIG. 2 is a perspective view of a frame assembly according to the first embodiment of the invention.

FIG. 3 is an exploded perspective view of FIG. 2,

FIG. 4 is a partial enlarged exploded perspective view along line A-A of FIG. 2.

FIG. 5 shows the view of FIG. 4 flipped.

FIGS. 6 and 7 are the plan and side views of the fixture in FIG. 4.

FIGS. 8 and 9 are the plan and side views of the stud in FIG. 4.

FIG. 10 is a partial enlarged side sectional view of the assembled state in FIG. 4.

FIG. 11 is a drawing showing the disassembled state of FIG. 10.

FIG. 12 is a partial enlarged view of FIG. 10.

FIGS. 13 to 18 are drawings showing the second embodiment of the invention.

FIGS. 19 to 21 are drawings showing the third embodiment of the invention,

FIG. 22 is a drawing showing a modified example of the stud according to the first embodiment.

### DETAILED DESCRIPTION OF EXEMPLARY EMBODIMENTS

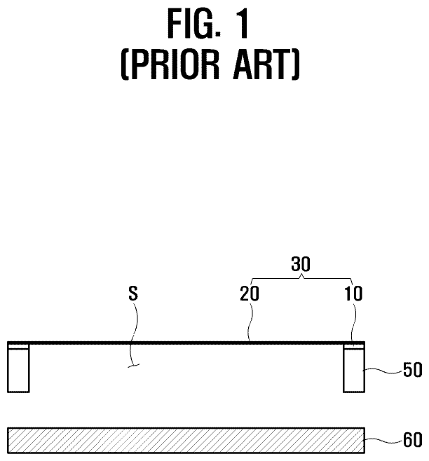

The following describes this invention in detail with reference to the accompanying drawings. In the description of this disclosure, the detailed explanation of the general structure of the pellicle 30 and the frame 50 is omitted, and the content described referring to FIG. 1 in the explanation of the prior art is adopted. The same reference numerals are used for components in FIG. 1 that are identical to those in this invention.

The present disclosure has been devised to solve the above problems, and it is an object of the present disclosure to provide a frame assembly that does not require high precision frame positioning alignment during the process of coupling the photomask and the frame, and allows for very easy separation of the frame from the photomask.

Another object of the present disclosure is to provide a frame assembly that eliminates the need for a process to form separate ventilation holes in the frame.

Still another object of the present disclosure is to provide a frame assembly that minimizes the phenomenon of adhesive acting as particles between the frame and the photomask.

According to the present disclosure, the frame and the photomask are bound by the shape matching between the protrusion of the stud and the coupling recess of the fixture and by the magnetic force between the fixture and the stud. This makes it unnecessary to precisely align the frame's position during the process of mounting the frame on the photomask and facilitates the separation of the frame from the photomask for reuse.

Additionally, the gap formed between the frame and the photomask by the stud creates ventilation, eliminating the need for a process to form separate ventilation holes in the frame.

Furthermore, the use of adhesive is reduced and the adhesive is not exposed to the exterior, minimizing the occurrence of particles and out-gassing caused by the adhesive.

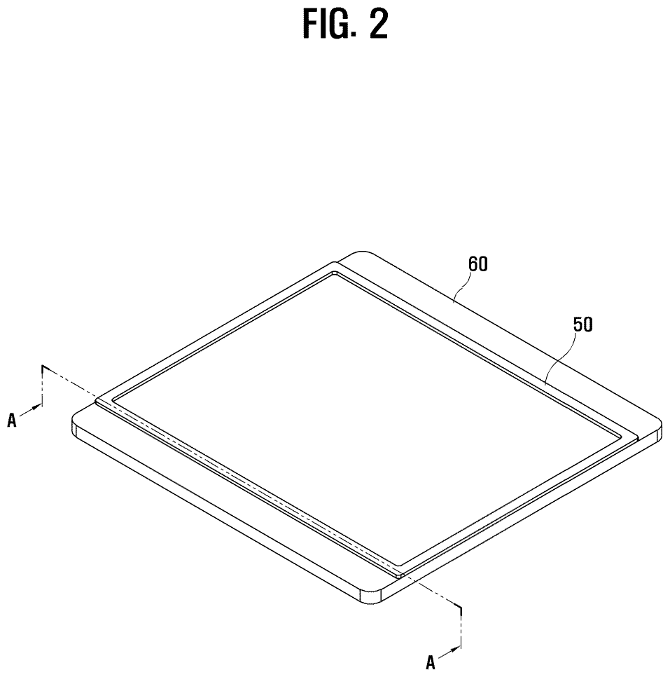

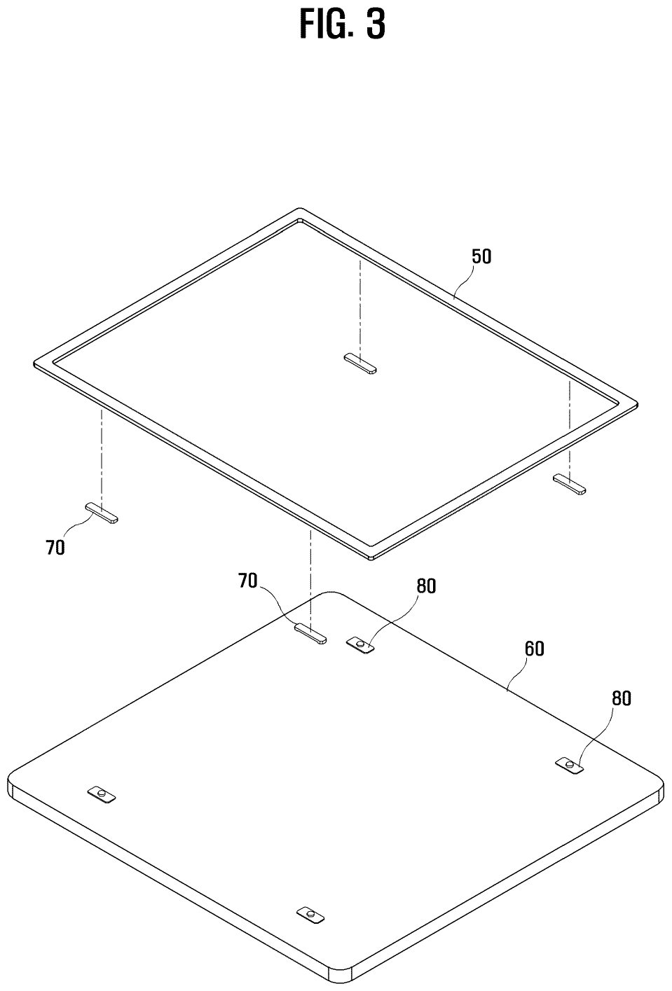

FIG. 2 is a perspective view of a frame assembly according to the first embodiment of this invention, and FIG. 3 is an exploded perspective view of FIG. 2.

The frame assembly according to the presently claimed invention can be applied to photomasks 60 used in photolithography processes for manufacturing semiconductors and FPDs (Flat Panel Displays), particularly suitable for photomasks 60 in Extreme Ultraviolet (EUV) photolithography processes.

The frame assembly is mounted on the photomask 60 with the pellicle 30 attached to its top, thus providing means for mounting the pellicle 30 on the photomask 60. The frame assembly of this invention includes a frame 50 and also comprises a fixture 70 and a stud 80. The photomask 60 has a micro circuit pattern (not shown) formed on its upper surface for the transfer process using EUV exposure light. It is typically formed on a quartz substrate used in EUV exposure processes and can be applied regardless of the size and shape of the glass substrate.

The frame 50 can be formed in various shapes such as circular, triangular, square, and polygonal, typically in the form of a square frame, especially a rectangular frame. The frame 50 has general shapes and sizes applied in EUV exposure processes and can be varied in size and shape corresponding to the photomask 60. The frame 50 is made from materials such as Al, Ti, V, Cr, Mn, Fe, Co, Ni, Cu, Zn, Ga, Ge, Rb, Sr, Y, Zr, Nb, Mo, Ru, Rh, Pd, Ag, Hf, Ta, W, Pt, Au, SUS, Si, carbon steel, tool steel, ceramics, metal-ceramic composites, resin, or their alloys. While the pellicle 30 is attached to the upper side of the frame 50, it is omitted in FIG. 2.

The stud 80 is attached to the upper side of the photomask 60 between the photomask 60 and frame 50. The fixture 70 is attached to the lower side of the frame 30 on the position corresponding to the stud 80 between the photomask 60 and frame 50. The stud 80 and fixture 70 are bonded together by magnetic force, forming pairs and binding together.

Both the stud 80 and the fixture 70 can be made from magnetic materials (magnets), or only one of them may be made from a magnetic material. The term magnetic material refers to materials that are magnetized by a magnetic field, including ferromagnetic, paramagnetic, and diamagnetic materials, encompassing all common magnets like Alnico, Ferrite, SmCo, Neodymium, rubber magnets, plastic magnets, and magnets made from rare earth metals. If only one of the stud 80 or fixture 70 is made from a magnetic material, the other can be made from a metal material or any material that can attach magnetically to a magnetic material.

Preferably, magnets made with rare earth metals are used, Generally, rare earth materials become magnets through a magnetization process after being mechanically processed into a certain shape by mixing raw materials, followed by applying a magnetic force. The magnetization process involves applying a strong magnetic field to align the materials in a certain direction, thereby inducing magnetism. Rare earth magnets, such as neodymium magnets, can have their magnetic strength and temperature of destruction set according to their material mix. If a rare earth magnet is heated beyond its working temperature, to a temperature where magnetic force is lost, it will lose its magnetism, but the lost magnetism can be restored through re-magnetization, Utilizing this principle, if the stud 80 or fixture 70, especially the fixture 70, Is made from a rare earth magnet with a specific temperature of magnetic force loss, it can be strongly held together by the magnetism during the exposure process, By applying heat exceeding the temperature of magnetic force loss externally, the magnetism of the magnetic body is lost, facilitating the separation of the stud 80 and fixture 70.

For the reuse of the frame 50, for instance, the fixture 70 that has lost its magnetism is detached from the frame 50, is re-magnetized through a magnetization process, and then is re-attached to the frame 50.

It is preferable for the surface of the stud 80 and fixture 70 to be coated with a metal or non-metal material to prevent out-gassing. For strong adhesive force due to mutual magnetism, the coating can be made from a metallic material.

The stud 80 and fixture 70 are attached at least once, and preferably, they are positioned in numbers and locations according to the shape of the frame 50 that can stably fix the frame 50 against forces (vibrational forces) arising from the movement direction of the stage that performs reciprocal motion during the exposure process.

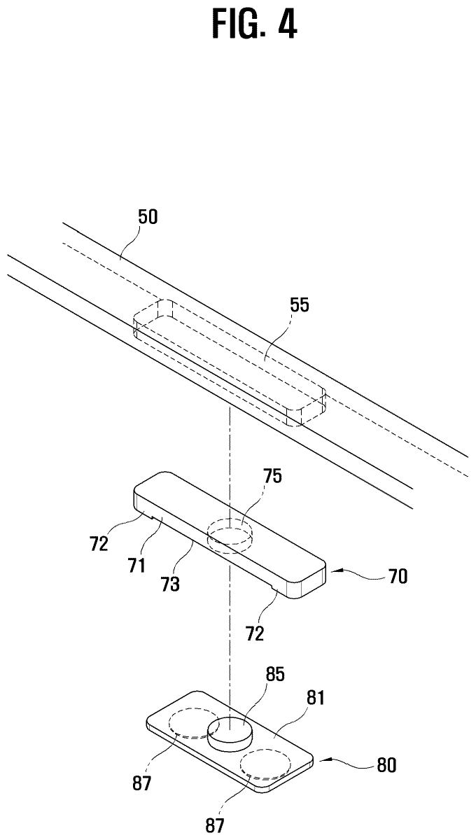

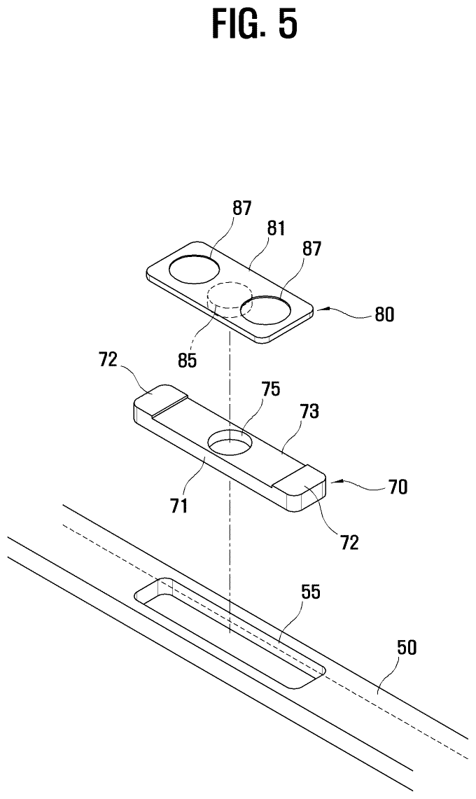

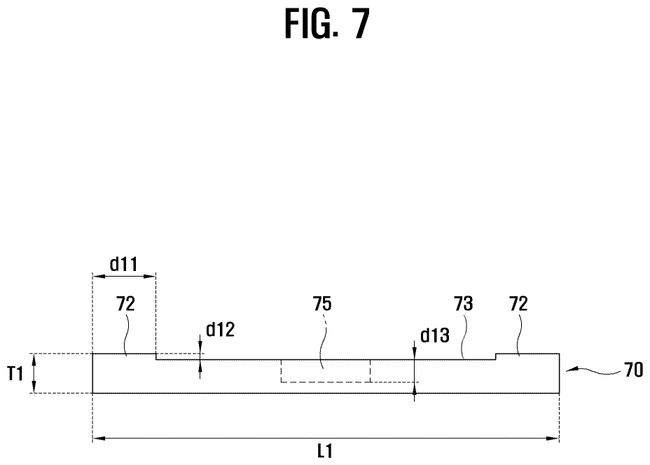

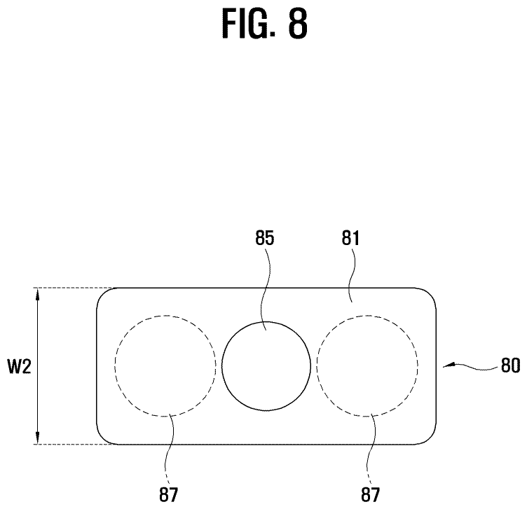

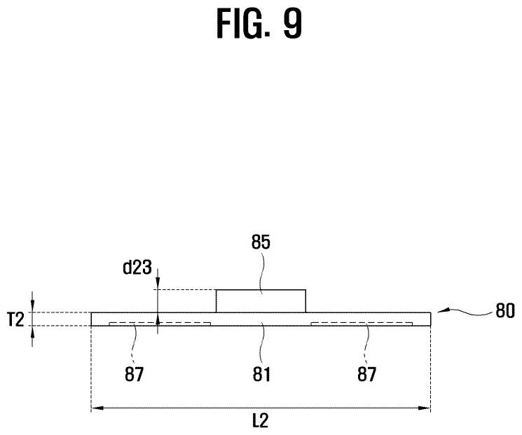

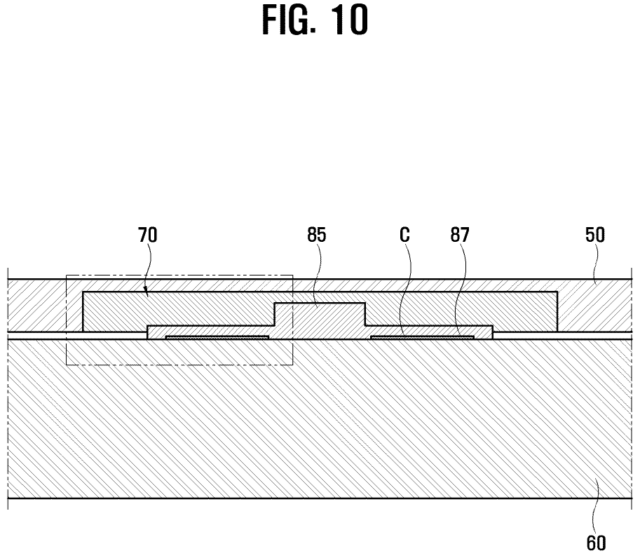

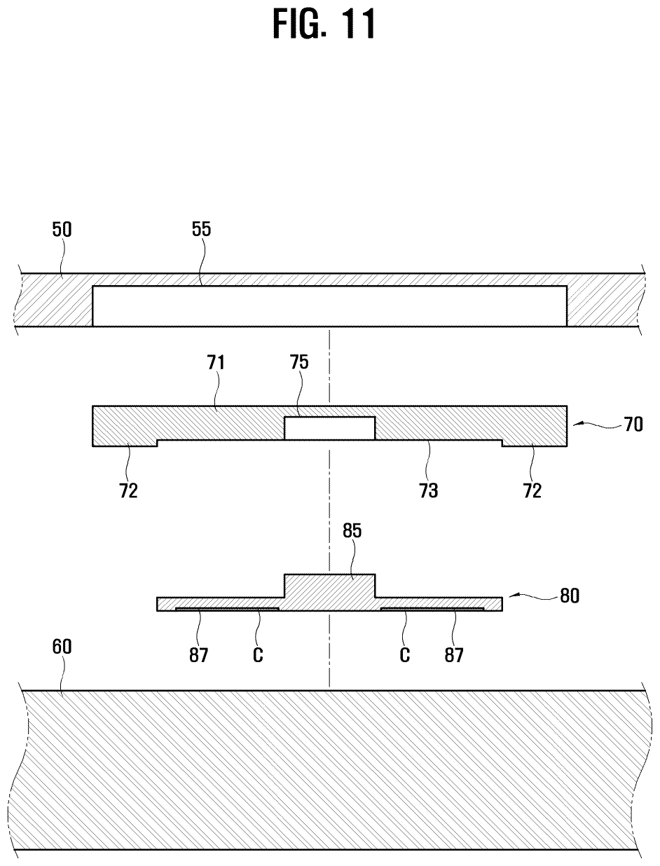

FIGS. 4 to 12 show the configuration of each part of the stud 80 and fixture 70 according to the first embodiment of the presently claimed invention and their assembled state.

The frame 50 has an insertion recess 55 formed on its bottom surface, and the fixture 70 is inserted and installed in the insertion recess 55. Once inserted into the insertion recess 55, it's preferable that the fixture 70 does not move. To ensure this, the insertion recess 50 has the same shape as the fixture 70 to allow for shape-matching coupling. The fixture 70 can be adhered by applying an adhesive in the Insertion recess 55, and preferably, it is coupled by press-fit without separate adhesive to ensure it does not detach and is securely coupled. The depth of the insertion recess 55 is preferably the same as the thickness of the fixture 70, specifically at the thickness of the support part 72 formed at both ends of the fixture 70. Thus, the fixture 70 inserted into the insertion recess 55 is positioned horizontally at the same level as the lower surface of the frame 50, neither protruding downwards from the lower surface of the frame 50 nor being embedded within the insertion recess 55.

The fixture 70 includes a fixture body 71 extending in the length direction of the frame 50, and support parts 72 protruding downwards at both ends of the fixture body 71, forming seating recess 73 where the stud 80 is seated. A coupling recess 75 is formed on the bottom surface of the seating recess 73, creating a two-step recessed shape with the seating recess 73 recessed and the coupling recess 75 further recessed inside the seating recess 73.

The stud 80 is equipped with a stud body 81. The stud body 81 is configured to match the length of the seating recess 73, thus preventing lateral movement of the stud 80 by shape-fitting within the seating recess 73. The stud 80 also features a protrusion 85 that fits into the coupling recess 75, doubly securing its position by being held in place by the support parts 72 of the fixture 70 and inserted into the coupling recess 75 for a shape-fitting connection. This structure ensures that the fixture 70 and stud 80 remain connected even under the strong forces generated by rapid reciprocal movements of the stage during the exposure process.

The cross-sectional shape of the fixture body 71 and stud body 81 can be circular, elliptical, triangular, square, or polygonal.

The protrusion 85 can be cylindrical or conical, with a cross-section that can be one or more shapes, such as circular, triangular, square, or polygonal, matching the shape of the coupling recess 75.

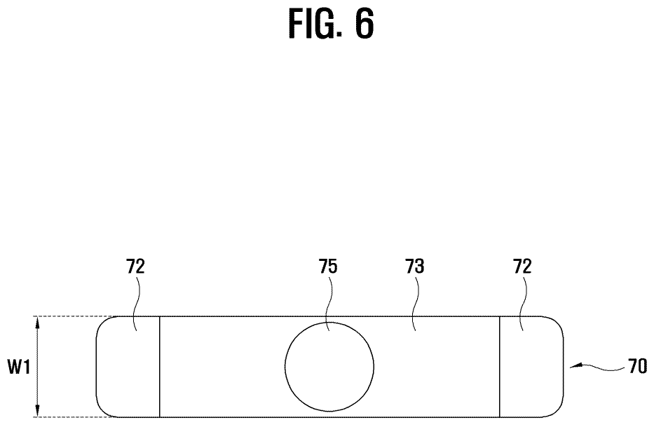

The sizes of the respective parts of the fixture 70 and the stud 80 are described with reference to FIGS. 6 to 9.

The fixture body 71 has a length (L1) of 5 to 150 mm, a width (W1) of 1 to 6 mm, and a thickness (T1) of 0.5 to 2 mm. The support part 72 has a length (d11) of 0.5 to 10 mm and a height (d12) from the bottom surface of the seating recess 73 of 0.1 to 1 mm. The coupling recess 75 has a depth (d13) of 0.1 to 1.5 mm.

The stud body 81 has a length (L2) of 4 to 130 mm, a width (W2) of 1 to 10 mm, and a thickness (T2) of 0.15 to 1.5 mm. If both the stud body 81 and fixture body 71 are made of magnetic material, the stud body 81 will have a width equal to or greater than that of the fixture body 71. If the fixture body 71 is made of a magnetic material and the stud body 81 is made of a material that attaches magnetically, it is preferable for the stud body 81 to have a larger width that the fixture body 71 as the strongest magnetic field is formed at the edge area of the fixture body 71.

The protrusion 85 of the stud 80 has a height (d23) of 0.1 to 1.5 mm, matching the depth (d13) of the coupling recess 75. For the process performance and the structural stability, the coupling recess 75 and the protrusion 81 are preferably 0.3 to 1 mm in depth (d13) and height (d23).

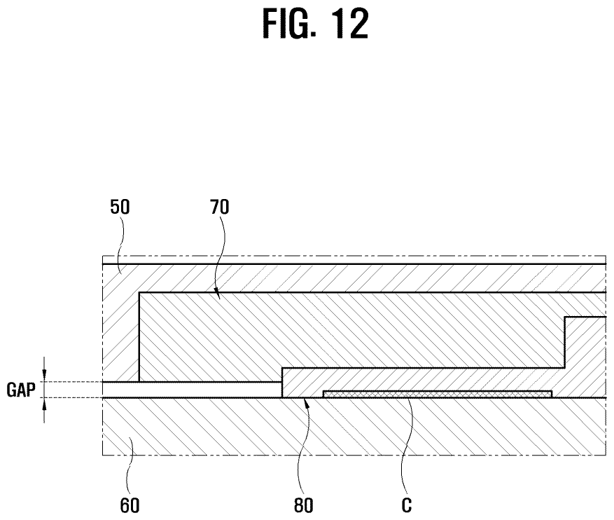

As shown in FIG. 12, a certain height of gap is formed between the lower side of the frame 50 and the upper side of the photomask 60. With the stud 80 and fixture 70 coupled, part of the thickness direction section of the stud body 81 protrudes outwards, forming a gap between the lower side of the frame 50 and the upper surface of the photomask 60. This gap, preferably formed to a height of 0.05 to 0.5 mm, functions as a venting hole, connecting the internal space(S) formed by the pellicle 30 and frame 50 with the external space thereof.

The stud body 81 has an adhesive recess 87 formed on the lower side thereof. Adhesive (C) is applied within the adhesive recess 87, serving to bond the stud body 81 to the photomask 60. Since the adhesive (C) is contained within the recessed adhesive recess 87, in the assembled state as shown in FIG. 12, it does not leak outwards, minimizing particle generation caused by the adhesive (C).

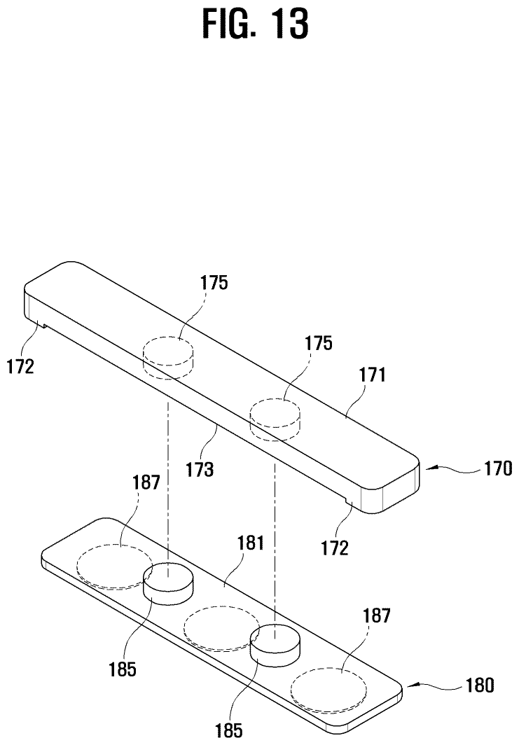

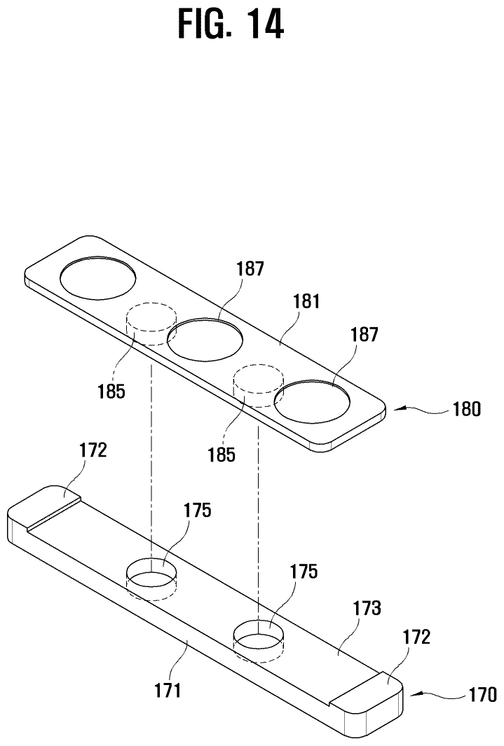

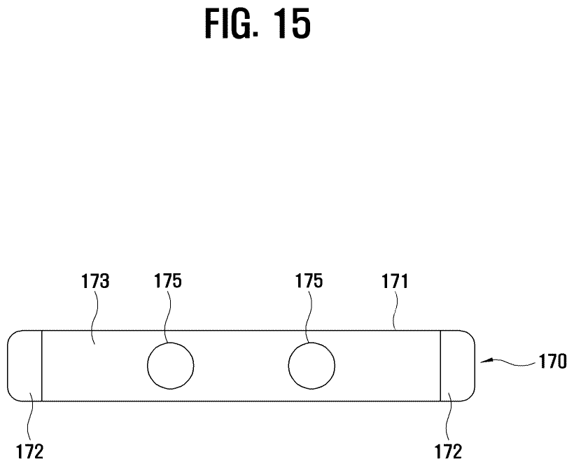

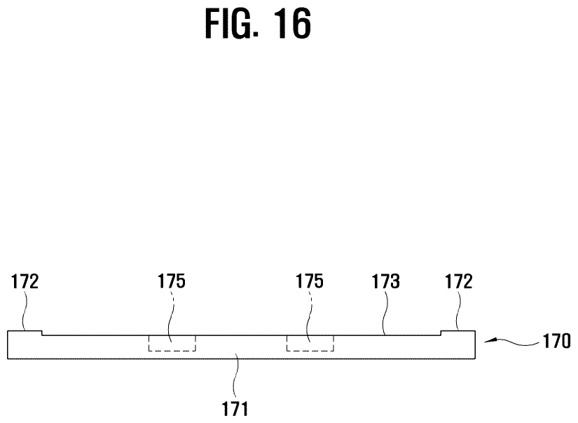

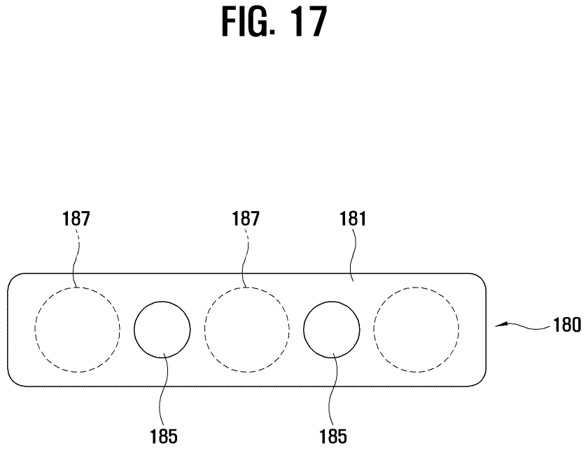

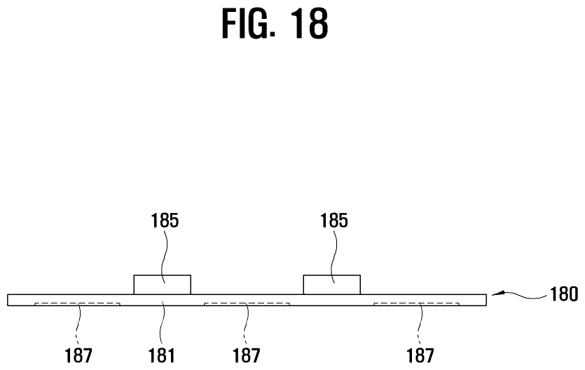

FIGS. 13 to 18 illustrate the second embodiment of the presently claimed invention. In this embodiment, the stud 180 is equipped with two protrusions 185, corresponding to two coupling recesses 175 in the fixture 170. The configuration of the stud 180 having a stud body 181, and the fixture 170 having a fixture body 171, support parts 172, and seating recesses 173 is the same as the first embodiment. The lengths of the stud 180 and fixture 170 in this embodiment are longer than in the first embodiment, providing a more robust connection between the photomask 60 and the frame 50 during the exposure process in which the photomask 60 moves in the length direction of the frame. The number of coupling recesses 175 and protrusions 185 on the fixture 170 and stud 180 can vary, taking into account the forces generated during the reciprocating movement in the exposure process and the fastening strength between the fixture 170 and stud 180,

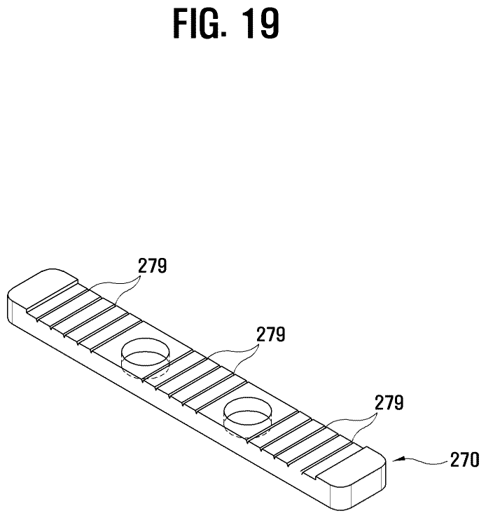

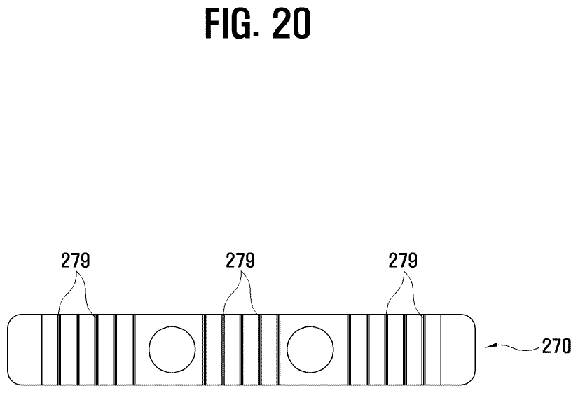

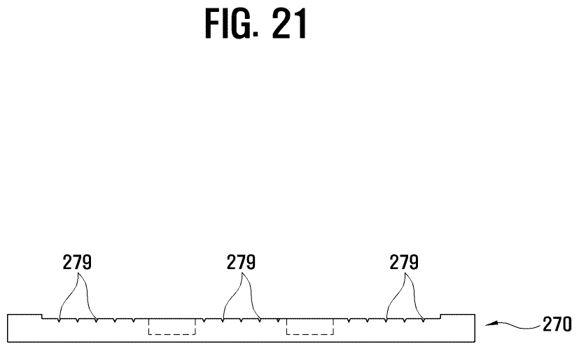

FIGS. 19 to 21 depict the third embodiment of the presently claimed invention. In this embodiment, the fixture 270 is basically the same as in the second embodiment but additionally includes a magnetic enhancement part 279. The magnetic enhancement part 279 is formed as one or more grooves 279, preferably multiple, recessed on the outside surface of the fixture 270. When the fixture 270 is made of magnetic material, the strongest magnetic field is formed at the boundary areas including the edge parts of the fixture body 71. Thus, forming multiple magnetic enhancement parts 279 can strengthen the bond between the fixture 70 and stud 80. The dimensions of the magnetic enhancement part 279, such as length, depth, and width, are not limited.

Moreover, the magnetic enhancement part 279 can be formed not only as grooves as shown but also as ribs protruding from the fixture body 71, or in various other shapes, such as projections or recesses protruding from or recessed into the surface of the fixture 270.

While this embodiment Illustrates the magnetic enhancement part 279 formed on the fixture 270, it can also be formed on the stud or both the fixture 270 and stud, either in independent shapes or in interlocking shapes that complement each other for coupling.

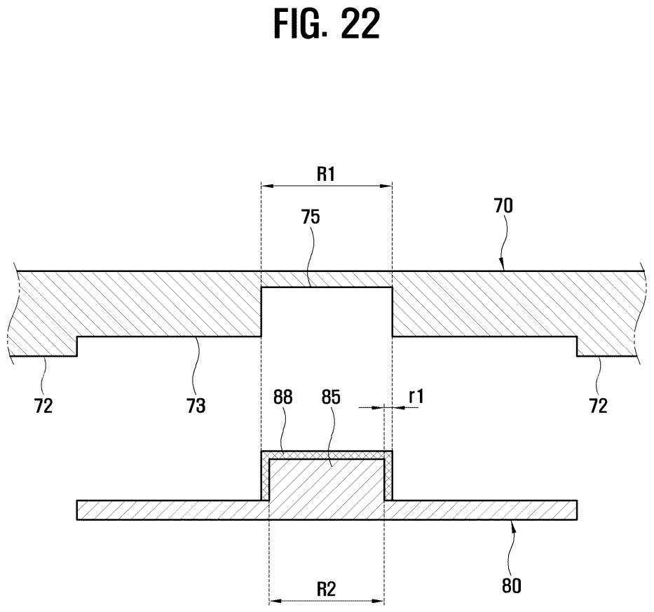

FIG. 22 illustrates a modified example of the stud according to the first embodiment.

In this embodiment, the coupling recess 75 of the fixture 70 is larger than the protrusion 85 of the stud 80. Specifically, when both the protrusion 85 and the coupling recess 75 have a circular cross-section, the diameter (R1) of the coupling recess 75 is larger than the diameter (R2) of the protrusion 85. The protrusion 85 is equipped with an elastic part 88 on its outer surface. The elastic part 88 is made from one or more of the following materials: metal, plastic, resin, and silicone, and is attached to the outer surface of the protrusion 85 either by fitting or coating. The thickness (r1) of the elastic part 88 is set so that the overall size of the protrusion 85 including the elastic part 88, I.e., R2+2r1, is equal to or slightly larger than the size of the coupling recess 75, i.e., R1. Therefore, when the protrusion 85 and the elastic part 88 are inserted into the coupling recess 75, they are inserted in a manner similar to being press-fitted, thereby strengthening the bond between the fixture 70 and the stud 80. This modification can also be applied to the second and third embodiments previously described.

Although details of the disclosure have been described above through a few embodiments of the disclosure with reference to the accompanying drawings, the embodiments are merely for the illustrative and descriptive purposes only but not construed as limiting the scope of the disclosure defined in the appended claims. It will be understood by a person having ordinary skill in the art that various changes and other equivalent embodiments may be made from these embodiments. Thus, the scope of the invention should be defined by the technical subject matters of the appended claims.

What is claimed is:

1. A frame assembly for mounting a pellicle on a photomask used in a photolithography process, comprising:
a frame mounted on the photomask, the frame on which the pellicle is attached;
a stud attached to an upper side of the photomask, the stud being disposed between the photomask and the frame; and
a fixture installed by being inserted into a lower side of the frame at a position corresponding to the stud between the photomask and the frame;
wherein the stud and the fixture are magnetically bonded to each other, and when bonded, the stud positioned beneath the fixture creates a gap of a certain height between the photomask and the frame.

2. The frame assembly of claim 1, wherein one of the stud and the fixture is made of a magnetic material and the other is made of a material that bonds magnetically with the magnetic material.

3. The frame assembly of claim 1, wherein the magnetic material includes a rare earth material that loses magnetism at a temperature exceeding a magnetic loss temperature thereof.

4. The frame assembly of claim 1, wherein an insertion recess is formed on the lower side of the frame for the fixture to be inserted.

5. The frame assembly of claim 1, wherein the certain height of the gap is 0.05˜0.5 mm.

6. The frame assembly of claim 1, wherein at least one of the stud and the fixture is surface-coated with a metal or non-metal material.

7. The frame assembly of claim 1, wherein
the fixture comprises a fixture body extending in a length direction of the frame, and support parts protruding downward at both ends of the fixture body so as to form a seating recess for the stud, and
the stud comprises a stud body that is prevented from moving in the length direction by being seated to be shape-matched in the seating recess.

8. The frame assembly of claim 7, wherein
the fixture has a coupling recess formed on a bottom surface of the seating recess, and
the stud has a protrusion that is coupled to be shape-matched with the coupling recess.

9. The frame assembly of claim 7, wherein
the fixture body has a length of 5˜150 mm in the length direction, a width of 1˜6 mm, and a thickness of 0.5˜2 mm;
the support part has a length of 0.5˜10 mm in the length direction, and a height of 0.1˜1 mm from the bottom surface of the seating recess;
the stud body has a length of 4˜130 mm in the length direction, a width of 1˜10 mm, and a thickness of 0.15˜1.5 mm; and
the protrusion has a height of 0.1˜1.5 mm.

10. The frame assembly of claim 7, wherein the stud body has the width equal to or greater than the width of the fixture body.

11. The frame assembly of claim 1, wherein at least one of the stud and the fixture is formed with a magnetic enhancement part having a shape protruding from or recessed into a surface thereof, the magnetic enhancement part for enhancing magnetic force.

12. The frame assembly of claim 7, wherein
the fixture has a coupling recess formed on a bottom surface of the seating recess,
the stud has a protrusion that couples with the coupling recess, the coupling recess is larger than the protrusion, and
the protrusion has an elastic part on an outside thereof that is inserted into the coupling recess together with the protrusion.

13. The frame assembly of claim 12, wherein the elastic part is formed from at least one of metal, plastic, resin, and silicon.
